(19) United States
(12) Patent Application Publication
(10) Pub. No.: US 2013/0307106 A1
(43) Pub. Date: Nov. 21, 2013

(54) SOLID-STATE IMAGING DEVICE

(71) Applicant: Yoshitaka EGAWA, Kanagawa (JP)

(72) Inventor: Yoshitaka EGAWA, Kanagawa (JP)

(73) Assignee: Kabushiki Kaisha Toshiba, Tokyo (JP)

(21) Appl. No.: 13/585,107

(22) Filed: Aug. 14, 2012

(30) Foreign Application Priority Data
May 16, 2012 (JP) 2012-112541

(51) Int. Cl. H01L 31/0232

(52) U.S. Cl. 257/432; 257/E31.127

(57) ABSTRACT

According to one embodiment, a solid-state imaging device includes a first collecting element configured to collect lights which are incident on a first photoelectric conversion layer and a third photoelectric conversion layer; and a second collecting element having a larger collecting area than a collecting area of the first collecting element and configured to collect a light which is incident on a second photoelectric conversion layer.

### CROSS-REFERENCE TO RELATED APPLICATIONS

This application is based upon and claims the benefit of priority from Japanese Patent Application No. 2012-112541, filed on May 16, 2012; the entire contents of which are incorporated herein by reference.

### FIELD

Embodiments according to the present invention relate to a solid-state imaging device.

### BACKGROUND

In recent years, a camera muddle to be provided on a portable telephone or the like is demanded to have a reduced thickness and an enhanced resolution. In order to cope with the reduction in the thickness of the camera module and the enhancement in the resolution, a refinement of a pixel in an image sensor is advanced. When a pixel area is reduced, the image sensor has a light quantity for an incidence on a pixel which is decreased. For this reason, a signal quantity is decreased so that a signal-to-noise ratio (SNR) is reduced. In the image sensor, therefore, it is desirable to implement an increase in a sensitivity through an enhancement in a light utilization efficiency.

### BRIEF DESCRIPTION OF THE DRAWINGS

FIG. 1 is a block diagram showing a schematic structure of a solid-state imaging device according to a first embodiment;

FIG. 2 is a circuit diagram showing an example of a structure of four pixels in a Bayer array of the solid-state imaging device illustrated in FIG. 1;

FIG. 3 is a cross-sectional view showing an example of a structure of a pixel cell in the solid-state imaging device according to the first embodiment;

FIG. 4A is a view showing a potential distribution along an A1-A2 line in FIG. 3, FIG. 4B is a view showing a potential distribution along a B1-B2 line in FIG. 3, and FIG. 4C is a view showing a potential distribution along a C1-C2 line in FIG. 3;

FIG. 5A is a plan view showing an example of a structure of a microlens in FIG. 3, FIG. 5B is a plan view showing an example of a structure of a color filter in FIG. 3, FIG. 5C is a plan view showing an example of a structure of a third concentration distribution layer in FIG. 3, and FIG. 5D is a plan view showing an example of a structure of a first concentration distribution layer in FIG. 3;

FIG. 6A is a plan view showing an example of a structure of a microlens in a solid-state imaging device according to a second embodiment, and FIG. 6B is a plan view showing an example of a structure of a color filter in the solid-state imaging device according to the second embodiment;

FIG. 7 is a cross-sectional view showing an example of a structure of a pixel cell in a solid-state imaging device according to a third embodiment;

FIG. 8A is a plan view showing an example of a structure of a microlens in FIG. 7, FIG. 8B is a plan view showing an example of a structure of a color filter in FIG. 7, FIG. 8C is a plan view showing an example of a structure of a third concentration distribution layer in FIG. 7, and FIG. 8D is a plan view showing an example of a structure of a first concentration distribution layer in FIG. 7;

FIG. 9 is a cross-sectional view showing an example of a structure of a pixel cell in a solid-state imaging device according to a fourth embodiment;

FIG. 10A is a plan view showing an example of a structure of a microlens in FIG. 9, FIG. 10B is a plan view showing an example of a structure of a color filter in FIG. 9, FIG. 10C is a plan view showing an example of a structure of a third concentration distribution layer in FIG. 9, and FIG. 10D is a plan view showing an example of a structure of a first concentration distribution layer in FIG. 9;

FIG. 11 is a cross-sectional view showing an example of a structure of a pixel cell in a solid-state imaging device according to a fifth embodiment;

FIG. 12A is a plan view showing an example of a structure of a microlens in FIG. 11, FIG. 12B is a plan view showing an example of a structure of a first concentration distribution layer in FIG. 11, FIG. 12C is a plan view showing an example of a structure of a second concentration distribution layer in FIG. 11, and FIG. 12D is a plan view showing an example of a structure of a fourth concentration distribution layer in FIG. 11;

FIG. 13 is a cross-sectional view showing an example of a structure of a pixel cell in a solid-state imaging device according to a sixth embodiment;

FIG. 14A is a view showing a potential distribution along an A3-A4 line in FIG. 13, FIG. 14B is a view showing a potential distribution along a B3-B4 line in FIG. 13, FIG. 14C is a view showing a potential distribution along a C3-C4 line in FIG. 13, and FIG. 14D is a view showing a potential distribution along a D3-D4 line in FIG. 13;

FIG. 15A is a plan view showing an example of a structure of a microlens in FIG. 13, FIG. 15B is a plan view showing an example of a structure of a first concentration distribution layer in FIG. 13, FIG. 15C is a plan view showing an example of a structure of a third concentration distribution layer in FIG. 13, and FIG. 15D is a plan view showing an example of a structure of a fifth concentration distribution layer in FIG. 13;

FIG. 16 is a cross-sectional view showing an example of a structure of a pixel cell in a solid-state imaging device according to a seventh embodiment;

FIG. 17A is a plan view showing an example of a structure of a first concentration distribution layer in FIG. 16, FIG. 17B is a plan view showing an example of a structure of a second concentration distribution layer in FIG. 16, FIG. 17C is a plan view showing an example of a structure of a fourth concentration distribution layer in FIG. 16, and FIG. 17D is a plan view showing an example of a structure of a sixth concentration distribution layer in FIG. 16;

FIG. 18 is a cross-sectional view showing an example of a structure of a pixel cell in a solid-state imaging device according to an eighth embodiment;

FIG. 19A is a plan view showing an example of a structure of a microlens in FIG. 18, FIG. 19B is a plan view showing an example of a structure of a color filter in FIG. 18, FIG. 19C is a plan view showing an example of a structure of a third concentration distribution layer in FIG. 18, and FIG. 19D is a plan view showing an example of a structure of a first concentration distribution layer in FIG. 18; and

FIGS. 20A and 20B are charts showing a spectral characteristic of a magenta filter which is to be applied to a solid-state imaging device according to a ninth embodiment.

### DETAILED DESCRIPTION

According to the solid-state imaging device in accordance with one embodiment, there are provided a first photoelectric conversion layer, a second photoelectric conversion layer, a third photoelectric conversion layer, a first color filter, a second color filter, a first collecting element, and a second collecting element. The first photoelectric conversion layer is provided for a first wavelength range. The second photoelectric conversion layer is provided for a second wavelength range so as not to overlap with the first photoelectric conversion layer in a depth direction. The third photoelectric conversion layer is provided for a third wavelength range in such a manner that at least a part overlaps with the first photoelectric conversion layer in the depth direction. The first color filter is provided for the first photoelectric conversion layer and the third photoelectric conversion layer and transmits lights of the first wavelength range and the third wavelength range. The second color filter is provided for the second photoelectric conversion layer and transmits a light in the second wavelength range. The first collecting element collects lights which are incident on the first photoelectric conversion layer and the third photoelectric conversion layer. The second collecting element has a larger collecting area than that of the first collecting element and collects a light which is incident on the second photoelectric conversion layer.

Solid-state image pickup devices according to embodiments will be described below with reference to the drawings. The present invention is not restricted to these embodiments.

### First Embodiment

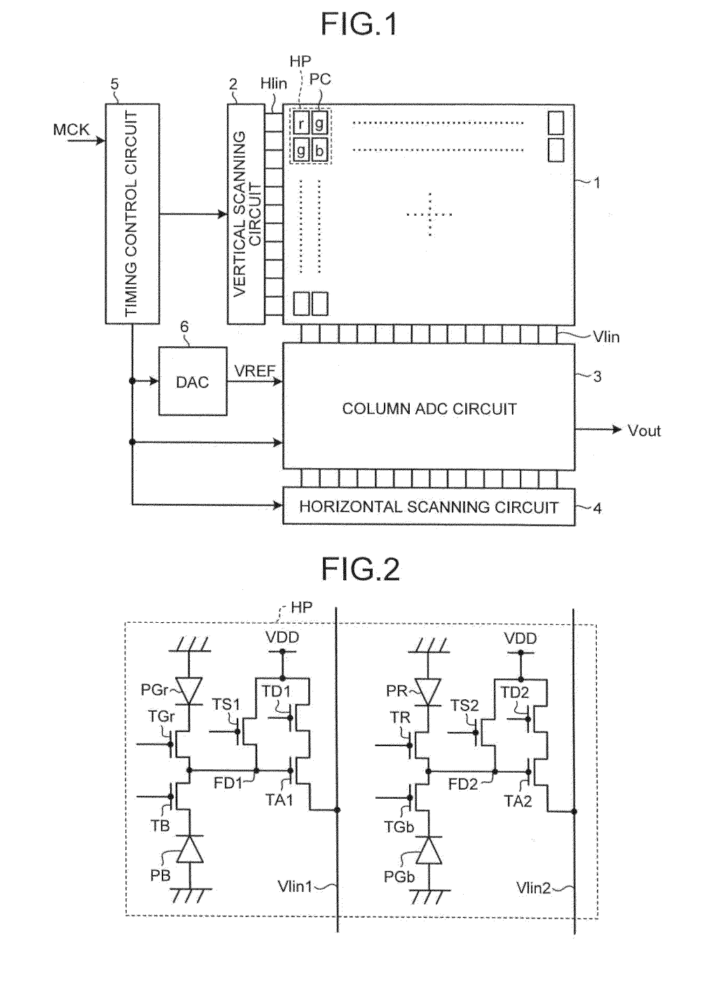

FIG. 1 is a block diagram showing a schematic structure of a solid-state imaging device according to a first embodiment of the present invention.

In FIG. 1, the solid-state imaging device is provided with a pixel array unit 1 in which a pixel PC for storing an electric charge converted photoelectrically is disposed in a matrix in a row direction and a column direction, a vertical scanning circuit 2 for scanning the pixel PC to be a reading target in a vertical direction, a column ADC circuit 3 for detecting a signal component of each pixel PC through CDS, a horizontal scanning circuit 4 for scanning the pixel PC to be the reading target in a horizontal direction, a timing control circuit 5 for controlling a timing for reading or storing each pixel PC, and a reference voltage generating circuit 6 for outputting a reference voltage VREF to the column ADC circuit 3. A master clock MCK is input to the timing control circuit 5.

In the pixel array unit 1, a horizontal control line Hlin for carrying out a reading control for the pixel PC is provided in the row direction and a vertical signal line Vlin for transmitting a signal read from the pixel PC is provided in the column direction.

In the pixel array unit 1, moreover, it is possible to form a Bayer array HP in which four pixels PC make a set. In the Bayer array HP, two green pixels g are disposed in one of diagonal directions and a single red pixel r and a single blue pixel b are disposed in the other diagonal direction.

The pixel PC is scanned in the vertical direction through the vertical scanning circuit 2 so that the pixel PC in the row direction is selected and a signal read from the pixel PC is transmitted to the column ADC circuit 3 through the vertical signal line Vlin. A difference between a signal level of the signal read from the pixel PC and a reference level is taken so that a signal component of each pixel PC is detected through the CDS and is output as an output signal Vout. At this time, in the Bayer array HP, a luminance signal Y can be obtained in accordance with Y=0.69 g+0.3r+0.11b.

FIG. 2 is a circuit diagram showing an example of a structure of four pixels in the Bayer array of the solid-state imaging device in FIG. 1.

In FIG. 2, in the Bayer array HP, there are provided photodiodes PB, PR, PGr and PGb, row selecting transistors TD1 and TD2, amplifying transistors TA1 and TA2, reset transistors TS1 and TS2, and reading transistors TB, TR, TGr and TGb. The row selecting transistor TD1, the amplifying transistor TA1 and the reset transistor TS1 are shared by the photodiodes PB and PGr, and the row selecting transistor TD2, the amplifying transistor TA2 and the reset transistors TS2 are shared by the photodiodes PR and PGb. The reading transistors TB, TR, TGr and TGb are provided for every photodiodes PB, PR, PGr and PGb. Moreover, a floating diffusion FD1 is formed as a detecting node on a connecting point of the amplifying transistor TA1, the reset transistor TS1, and the reading transistors TB and TGr. A floating diffusion FD2 is formed as a detecting node on a connecting point of the amplifying transistor TA2, the reset transistor TS2, and the reading transistors TR and TGb.

A source of the reading transistor TGr is connected to the photodiode PGr, a source of the reading transistor TB is connected to the photodiode PB, a source of the reading transistor TR is connected to the photodiode PR, and a source of the reading transistor TGb is connected to the photodiode PGb. Moreover, a source of the reset transistor TS1 is connected to drains of the reading transistors TGr and TB, a source of the reset transistor TS2 is connected to drains of the reading transistors TGb and TR, and drains of the reset transistors TS1 and TS2 and the row selecting transistors TD1 and TD2 are connected to a power supply potential VDD. Moreover, a source of the amplifying transistor TA1 is connected to a vertical signal line Vlin1, a gate of the amplifying transistor TA1 is connected to drains of the reading transistors TGr and TB, and a drain of the amplifying transistor TA1 is connected to a source of the row selecting transistor TD1. A source of the amplifying transistor TA2 is connected to a vertical signal line Vlin2, a gate of the amplifying transistor TA2 is connected to drains of the reading transistors TGb and TR, and a drain of the amplifying transistor TA2 is connected to a source of the row selecting transistor TD2.

Although the description has been given to the case in which the row selecting transistors TD1 and TD2 are provided in the pixel in the example of FIG. 2, the pixel does not need to have the row selecting transistors TD1 and TD2. Although the description has been given to a 2-pixel 1-cell structure in the example of FIG. 2, moreover, it is also possible to employ a 4-pixel 1-cell structure or an 8-pixel 1-cell structure, which is not particularly restricted.

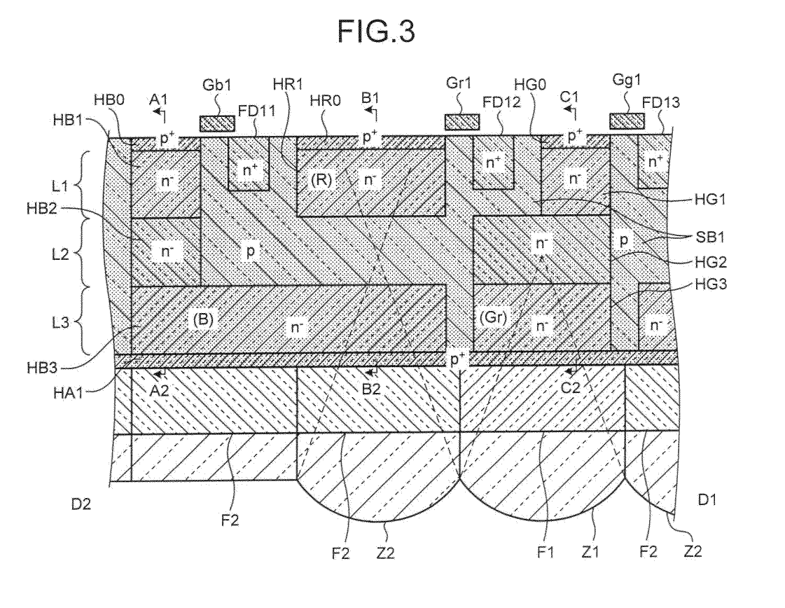

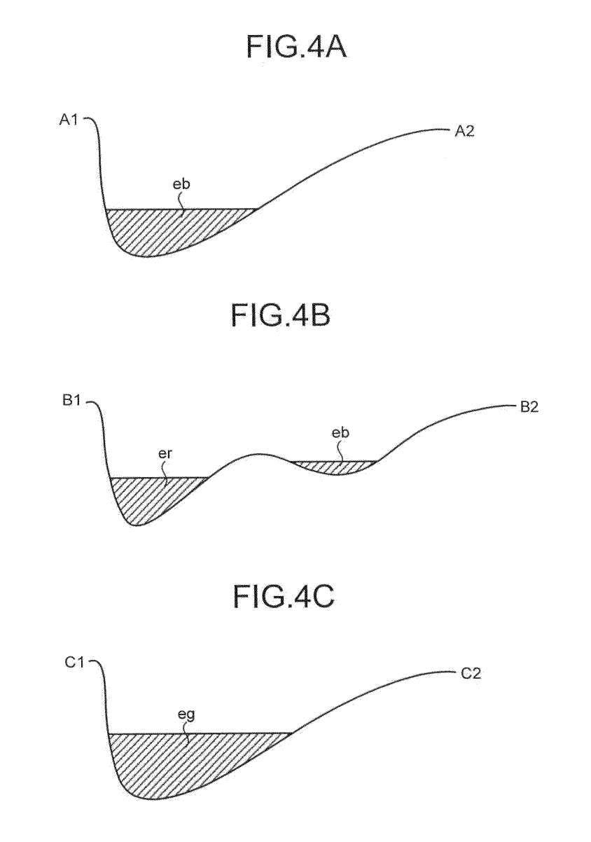

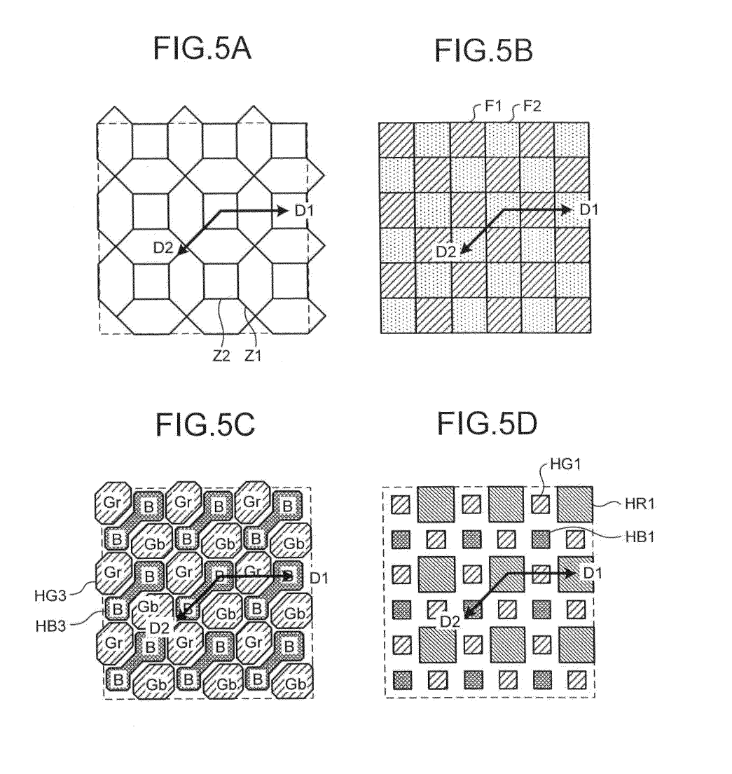

FIG. 3 is a cross-sectional view showing an example of a structure of a pixel cell in the solid-state imaging device according to the first embodiment. FIG. 4A is a view showing a potential distribution along an A1-A2 line in FIG. 3, FIG. 4B is a view showing a potential distribution along a B1-B2 line in FIG. 3, and FIG. 4C is a view showing a potential distribution along a C1-C2 line in FIG. 3. FIG. 5A is a plan view showing an example of a structure of a microlens in FIG. 3, FIG. 5B is a plan view showing an example of a structure of a color filter in FIG. 3, FIG. 5C is a plan view showing an example of a structure of a third concentration distribution layer in FIG. 3, and FIG. 5D is a plan view showing an example of a structure of a first concentration distribution layer in FIG. 3. FIG. 3 is a cross-sectional view taken along a D1-D2 line in FIGS. 5A to 5D. In the first embodiment, a backside-illumination type CMOS image sensor is taken as an example.

In FIG. 3 and FIGS. 5A to 5D, a first concentration distribution layer L1, a second concentration distribution layer L2 and a third concentration distribution layer L3 are sequentially formed on a semiconductor layer SB1 from a surface side toward a back side. For example, a material of the semiconductor layer SB1 can be selected from Si, Ge, SiGe, SiC, SiSn, PbS, GaAs, InP, InGaAsP, GaP, GaN, ZnSe and the like. Moreover, the semiconductor layer SB1 can be set into a p type.

A red photoelectric conversion layer R, green photoelectric conversion layers Gr and Gb and a blue photoelectric conversion layer B are formed on the semiconductor layer SB1. The red photoelectric conversion layer R can constitute the photodiode PR in FIG. 2. The green photoelectric conversion layer Gr can constitute the photodiode PGr in FIG. 2. The green photoelectric conversion layer Gb can constitute the photodiode PGb in FIG. 2. The blue photoelectric conversion layer B can constitute the photodiode PB in FIG. 2.

The green photoelectric conversion layers Gr and Gb are disposed so as not to overlap with the red photoelectric conversion layer R and the blue photoelectric conversion layer B in a depth direction. The blue photoelectric conversion layer B is disposed in such a manner that at least a part overlaps with the red photoelectric conversion layer R in the depth direction. Moreover, the blue photoelectric conversion layer B and the green photoelectric conversion layers Gr and Gb are constituted to have larger areas on the back side than areas on the surface side of the semiconductor layer SB1. In the case in which the semiconductor layer SB1 is formed of Si, it is preferable that the area of the blue photoelectric conversion layer B should be set to be increased in a depth of approximately 0.1 to 0.5 μm from the back side of the semiconductor layer SB1, the areas of the green photoelectric conversion layers Gr and Gb should be set to be increased in a depth of approximately 0.5 to 1.5 μm from the back side of the semiconductor layer SB1, and the area of the red photoelectric conversion layer R should be set to be increased in a depth of approximately 1.5 to 3.0 μm from the back side of the semiconductor layer SB1.

More specifically, the blue photoelectric conversion layer B is provided with impurity diffusion layers HB1 to HB3. The impurity diffusion layers HB1 to HB3 are disposed on the first concentration distribution layer L1, the second concentration distribution layer L2 and the third concentration distribution layer L3, respectively. The impurity diffusion layer HB3 has a larger area than the area of the impurity diffusion layer HB1. The impurity diffusion layer HB2 can have an area set to be equal to the area of the impurity diffusion layer HB1.

Impurity diffusion layers HG1 to HG3 are provided on the green photoelectric conversion layer Gr. The impurity diffusion layers HG1 to HG3 are disposed on the first concentration distribution layer L1, the second concentration distribution layer L2 and the third concentration distribution layer L3, respectively. The impurity diffusion layer HG3 has a larger area than the area of the impurity diffusion layer HG1. The impurity diffusion layer HG2 can have an area set to be equal to the area of the impurity diffusion layer HG3.

An impurity diffusion layer HR1 is provided on the red photoelectric conversion layer R. The impurity diffusion layer HR1 is disposed on the first concentration distribution layer L1. Moreover, the impurity diffusion layer HR1 is disposed in such a manner that at least a part overlaps with the impurity diffusion layer HB3 in the depth direction.

Furthermore, pinning layers HB0, HR0 and HG0 are formed on the impurity diffusion layers HB1, HR1 and HG1, respectively. A pinning layer HA1 is formed on the back face of the semiconductor layer SB1. The impurity diffusion layers HB1 to HB3, HG1 to HG3 and HR1 can be set into an n⁻ type. The pinning layers HB0, HR0, HG0 and HA1 can be set into a p⁺ type.

As shown in FIG. 4A, a laminated portion of the impurity diffusion layers HB1 to HB3 can have a downward gradient of a potential from the impurity diffusion layer HB3 toward the impurity diffusion layer HB1 in such a manner that an electric charge eb generated in the impurity diffusion layer HB3 can be moved to the impurity diffusion layer HB1. As shown in FIG. 4B, moreover, a laminated portion of the impurity diffusion layers HR1 and HB3 can have a peak of the potential between the impurity diffusion layers HR1 and HB3 in order to prevent an electric charge er generated in the impurity diffusion layer HR1 from being mixed into the electric charge eb generated in the impurity diffusion layer HB3. As shown in FIG. 4C, furthermore, a laminated portion of the impurity diffusion layers HG1 to HG3 can have a downward gradient of the potential from the impurity diffusion layer HG3 toward the impurity diffusion layer HG1 in such a manner that an electric charge eg generated in the impurity diffusion layers HG2 and HG3 can be moved to the impurity diffusion layer HG1.

In addition, floating diffusions FD11, FD12 and FD13 are formed in a clearance between the red photoelectric conversion layer R, the green photoelectric conversion layers Gr and Gb, and the blue photoelectric conversion layer B at the surface side of the semiconductor layer SB1. The floating diffusions FD11, FD12 and FD13 can be set into an n⁺ type. Moreover, the floating diffusions FD11 and FD13 can constitute the floating diffusion FD1 in FIG. 2, and the floating diffusion FD12 can constitute the floating diffusion FD2 in FIG. 2.

Moreover, a gate electrode Gb1 is disposed between the blue photoelectric conversion layer B and the floating diffusion FD11, a gate electrode Gr1 is disposed between the red photoelectric conversion layer R and the floating diffusion FD12, and a gate electrode Gg1 is disposed between the green photoelectric conversion layer Gr and the floating diffusion FD13 over the semiconductor layer SB1.

A green filter F1 and a magenta filter F2 are formed on the back side of the semiconductor layer SB1. The green filter F1 is disposed corresponding to the green photoelectric conversion layers Gr and Gb. The magenta filter F2 is disposed corresponding to the blue photoelectric conversion layer B and the red photoelectric conversion layer R.

Furthermore, a microlens Z1 is disposed on the green photoelectric conversion layer Gb and the green filter F1. A microlens Z2 is disposed on the magenta filter F2 in the same row as the green photoelectric conversion layer Gr. At this time, the microlens Z1 can have a larger collecting area than the microlens Z2.

A light collected by the microlens Z1 is incident on the green filter F1 so that a green light is extracted and is then incident on the green photoelectric conversion layers Gr and Gb. For example, the green light is photoelectrically converted in the green photoelectric conversion layer Gr so that the electric charge eg is generated and is then stored in the green photoelectric conversion layer Gr. A read voltage is applied to the gate electrode Gg1 so that the electric charge eg stored in the green photoelectric conversion layer Gr is read to the floating diffusion FD13.

On the other hand, a light collected by the microlens Z2 is incident on the magenta filter F2 so that a blue light and a red light are extracted and are then incident on the blue photoelectric conversion layer B and the red photoelectric conversion layer R. The blue light is photoelectrically converted in the blue photoelectric conversion layer B so that the electric charge eb is generated and is then stored in the blue photoelectric conversion layer B. A read voltage is applied to the gate electrode Gb1 so that the electric charge eb stored in the blue photoelectric conversion layer B is read to the floating diffusion FD11. Moreover, the red light is photoelectrically converted in the red photoelectric conversion layer R so that the electric charge er is generated and is then stored in the red photoelectric conversion layer R. A read voltage is applied to the gate electrode Gr1 so that the electric charge er stored in the red photoelectric conversion layer R is read to the floating diffusion FD12.

By causing the microlens Z1 to have a larger collecting area than the microlens Z2, it is possible to enhance a sensitivity of the green pixel g, thereby enhancing the S/N ratio of the luminance signal Y. For example, referring to a method of disposing the microlens Z1 and the microlens Z2 in FIG. 5A, the microlens Z1 is also disposed on the magenta filter F2 in the same row as the green photoelectric conversion layer Gb. Therefore, a light incident on the magenta filter F2 in the same row as the green photoelectric conversion layer Gb can be collected into the green photoelectric conversion layers Gr and Gb. Consequently, a light quantity can be increased to be 1.5 fold in the green photoelectric conversion layers Gr and Gb.

Moreover, the blue photoelectric conversion layer B and the red photoelectric conversion layer R are caused to overlap with each other in the depth direction, and furthermore, the green photoelectric conversion layers Gr and Gb are prevented from overlapping with the blue photoelectric conversion layer B and the red photoelectric conversion layer R. Consequently, it is possible to suppress a deterioration in a color isolation of the blue, green and red lights while increasing light receiving areas of the blue photographic conversion layer B and the red photoelectric conversion layer R. Therefore, it is possible to suppress a deterioration in a color reproducibility while enhancing a sensitivity and a saturation charge quantity of each of the blue pixel b and the red pixel r.

### Second Embodiment

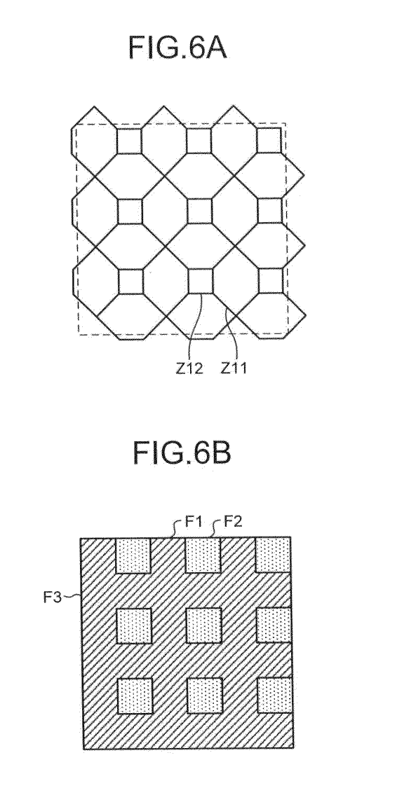

FIG. 6A is a plan view showing an example of a structure of a microlens in a solid-state imaging device according to a second embodiment, and FIG. 6B is a plan view showing an example of a structure of a color filter in the solid-state imaging device according to the second embodiment.

Although the microlens Z2 is set to have an equal size to the size of the magenta filter F2 in the example of FIG. 5A, a microlens Z12 has a smaller size than the size of the magenta filter F2 in the example of FIG. 6A. A size of a microlens Z11 is increased corresponding to the reduction in the size of the microlens Z12. For instance, by setting the size of the microlens Z12 to be a half of the size of the microlens Z2 and correspondingly increasing the size of the microlens Z11, it is possible to increase a light quantity to be 1.75 fold in green photoelectric conversion layers Gr and Gb.

Although the description has been given to the method of disposing the magenta filter F2 under the microlens Z1 in the same row as the green photoelectric conversion layer Gb in the example of FIG. 5B, moreover, a green filter F3 may be disposed under the microlens Z1 in the same row as the green photoelectric conversion layer Gb as shown in FIG. 6B.

### Third Embodiment

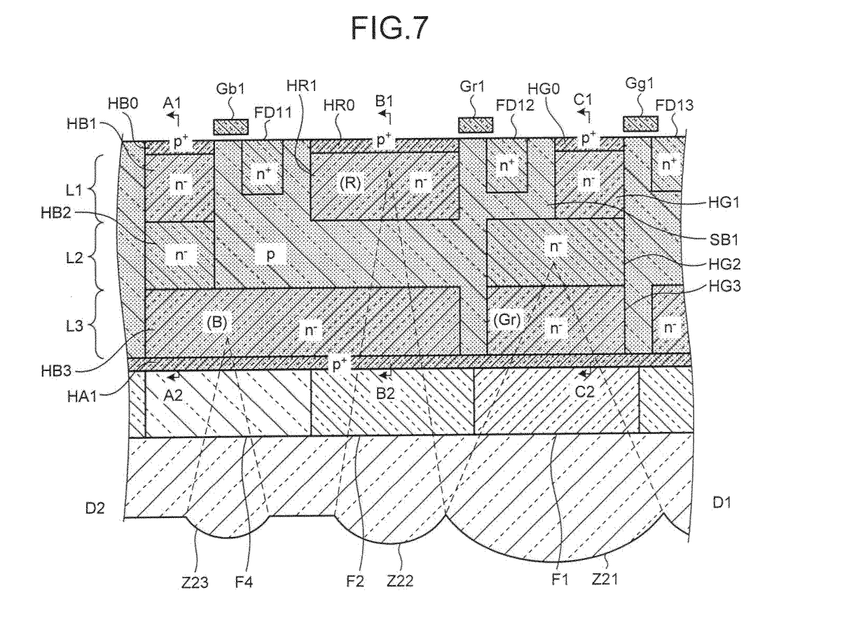

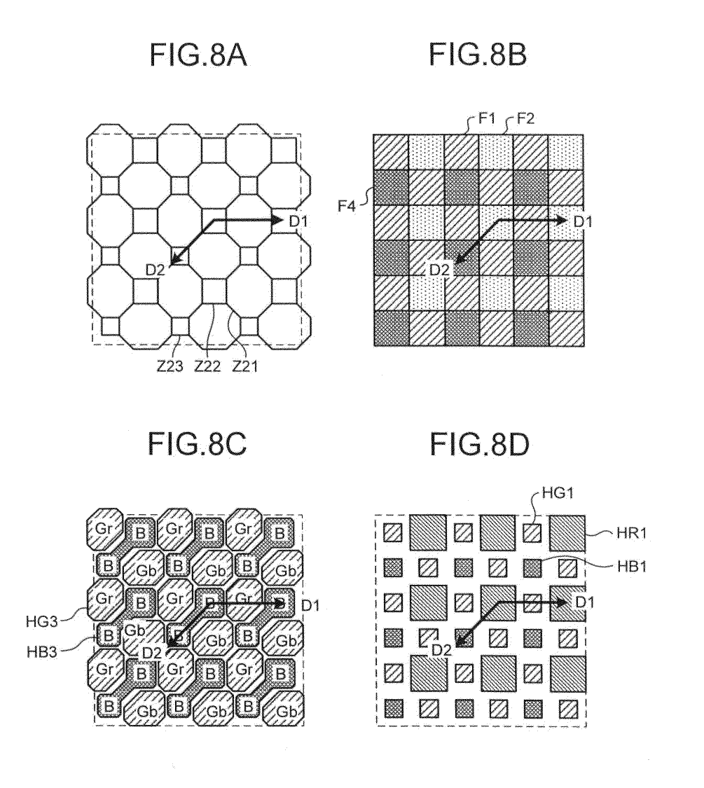

FIG. 7 is a cross-sectional view showing an example of a structure of a pixel cell in a solid-state imaging device according to a third embodiment. FIG. 8A is a plan view showing an example of a structure of a microlens in FIG. 7, FIG. 8B is a plan view showing an example of a structure of a color filter in FIG. 7, FIG. 8C is a plan view showing an example of a structure of a third concentration distribution layer in FIG. 7, and FIG. 8D is a plan view showing an example of a structure of a first concentration distribution layer in FIG. 7. In the third embodiment, a backside illumination type CMOS image sensor is taken as an example.

In FIG. 7 and FIGS. 8A to 8D, with the structure, a blue filter F4 is provided in place of the magenta filter F2 in the same row as the green photoelectric conversion layer Gb in FIG. 3 and FIGS. 5A to 5D. Moreover, microlenses Z21 to Z23 are provided in place of the microlenses Z1 and Z2 in FIG. 3 and FIGS. 5A to 5D. The microlens Z23 does not need to be always provided.

The microlens Z21 is disposed on a green filter F1, the microlens Z22 is disposed on a magenta filter F2, and the microlens Z23 is disposed on a blue filter F4. The microlens Z22 can be set to have a smaller size than the size of the magenta filter F2, and the microlens Z23 can be set to have a smaller size than the size of the blue filter F4. Corresponding to the reduction in the sizes of the microlenses Z22 and Z23, it is possible to increase the size of the microlens Z21. In other words, the microlens Z21 may be protruded over the magenta filter F2 and the blue filter F4.

A light collected by the microlens Z21 is incident on the green filter F1 so that a green light is extracted and is then incident on the green photoelectric conversion layers Gr and Gb. For example, the green light is photoelectrically converted in the green photoelectric conversion layer Gr so that an electric charge eg is generated.

On the other hand, a light collected by the microlens Z22 is incident on the magenta filter F2 so that a blue light and a red light are extracted and are then incident on the blue photoelectric conversion layer B and the red photoelectric conversion layer R. Moreover, a light collected by the microlens Z23 is incident on the blue filter F4 so that a blue light is extracted and is then incident on the blue photoelectric conversion layer B. The blue light is photoelectrically converted in the blue photoelectric conversion layer B so that an electric charge eb is generated and is then stored in the blue photoelectric conversion layer B. Furthermore, the red light is photoelectrically converted in the red photoelectric conversion layer R so that an electric charge er is generated and is then stored on the red photoelectric conversion layer R.

By providing the blue filter F4 on the blue photoelectric conversion layer B, it is possible to enhance a purity of the blue light which is incident on the blue photoelectric conversion layer B. Therefore, it is possible to enhance a color reproducibility of the blue color while improving an S/N ratio of a blue signal.

### Fourth Embodiment

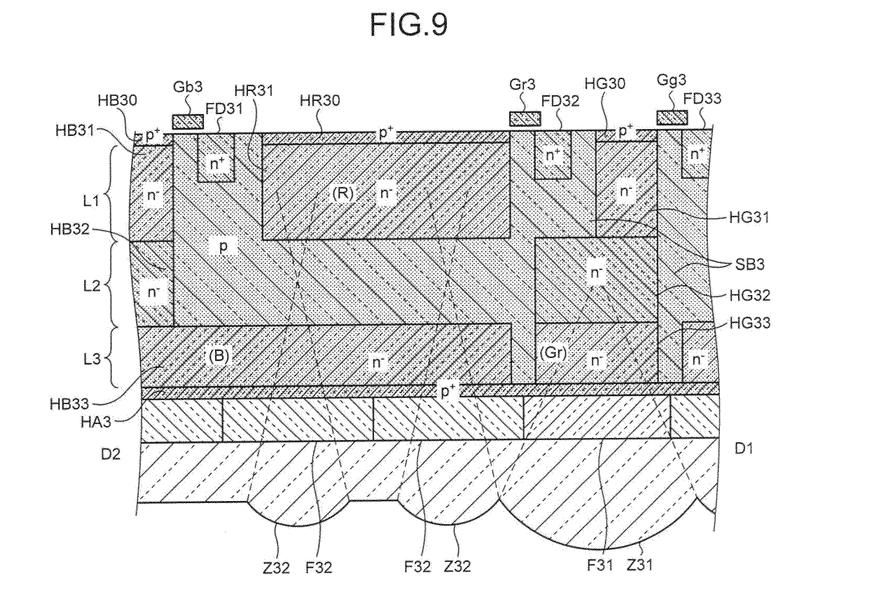

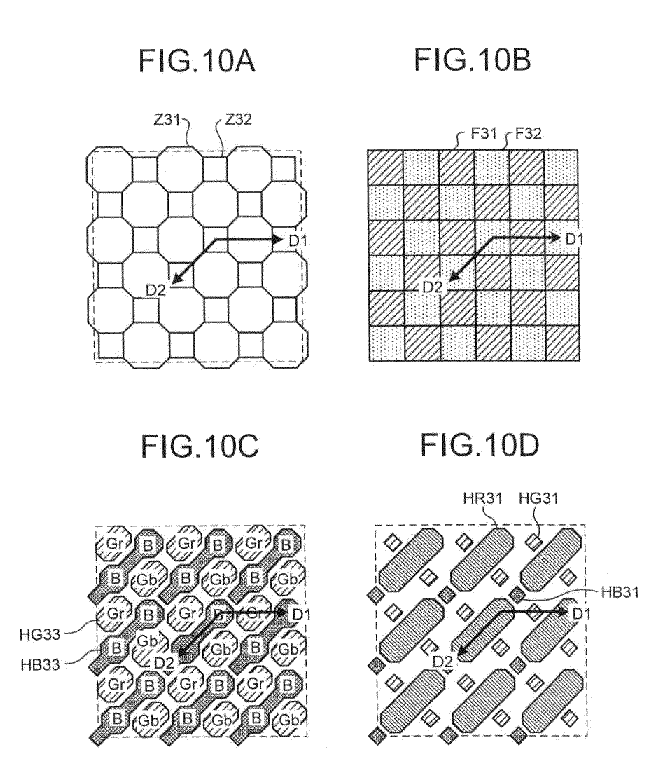

FIG. 9 is a cross-sectional view showing an example of a structure of a pixel cell in a solid-state imaging device according to a fourth embodiment. FIG. 10A is a plan view showing an example of a structure of a microlens in FIG. 9, FIG. 10B is a plan view showing an example of a structure of a color filter in FIG. 9, FIG. 10C is a plan view showing an example of a structure of a third concentration distribution layer in FIG. 9, and FIG. 10D is a plan view showing an example of a structure of a first concentration distribution layer in FIG. 9. In the fourth embodiment, a backside-illumination type CMOS image sensor is taken as an example.

In FIG. 9 and FIGS. 10A to 10D, a first concentration distribution layer L1, a second concentration distribution layer L2 and a third concentration distribution layer L3 are sequentially formed on a semiconductor layer SB3 from a surface side toward a back side. A red photoelectric conversion layer R, green photoelectric conversion layers Gr and Gb, and a blue photoelectric conversion layer B are formed on the semiconductor layer SB3.

The green photoelectric conversion layers Gr and Gb are disposed so as not to overlap with the red photoelectric conversion layer R and the blue photoelectric conversion layer B in a depth direction. The blue photoelectric conversion layer B is disposed in such a manner that at least a part overlaps with the red photoelectric conversion layer R in the depth direction. Moreover, the blue photoelectric conversion layer B and the green photoelectric conversion layers Gr and Gb are constituted to have larger areas on the back side than areas on the surface side of the semiconductor layer SB3.

More specifically, the blue photoelectric conversion layer B is provided with impurity diffusion layers HB31 to HB33. The impurity diffusion layers HB31 to HB33 are disposed on the first concentration distribution layer L1, the second concentration distribution layer L2 and the third concentration distribution layer L3, respectively. The impurity diffusion layer HB33 has a larger area than the area of the impurity diffusion layer HB31. The impurity diffusion layer HB32 can have an area set to be equal to the area of the impurity diffusion layer HB31. Moreover, the impurity diffusion layer HB33 can be disposed integrally over two adjacent pixels in a diagonal direction.

Impurity diffusion layers HG31 to HG33 are provided on the green photoelectric conversion layer Gr. The impurity diffusion layers HG31 to HG33 are disposed on the first concentration distribution layer L1, the second concentration distribution layer L2 and the third concentration distribution layer L3, respectively. The impurity diffusion layer HG33 has a larger area than the area of the impurity diffusion layer HG31. The impurity diffusion layer HG32 can have an area set to be equal to the area of the impurity diffusion layer HG33.

An impurity diffusion layer HR31 is provided on the red photoelectric conversion layer R. The impurity diffusion layer HR31 is disposed on the first concentration distribution layer L1. Moreover, the impurity diffusion layer HR31 is disposed in such a manner that at least a part overlaps with the impurity diffusion layer HB33 in the depth direction. Furthermore, the impurity diffusion layer HR31 can be disposed integrally over two adjacent pixels in the diagonal direction.

In addition, pinning layers HB30, HR30 and HG30 are provided on the impurity diffusion layers HB31, HR31 and HG31, respectively. A pinning layer HA3 is formed on the back face of the semiconductor layer SB3.

Moreover, floating diffusions FD31, FD32 and FD33 are formed in a clearance among the red photoelectric conversion layer R, the green photoelectric conversion layers Gr and Gb, and the blue photoelectric conversion layer B at the surface side of the semiconductor layer SB3.

Furthermore, a gate electrode Gb3 is disposed between the blue photoelectric conversion layer B and the floating diffusion FD31, a gate electrode Gr3 is disposed between the red photoelectric conversion layer R and the floating diffusion FD32, and a gate electrode Gg3 is disposed between the green photoelectric conversion layer Gr and the floating diffusion FD33 over the semiconductor layer SB3.

A green filter F31 and a magenta filter F32 are formed on the back side of the semiconductor layer SB3. The green filter F31 is disposed corresponding to the green photoelectric conversion layers Gr and Gb. The magenta filter F32 is disposed corresponding to the blue photoelectric conversion layer B and the red photoelectric conversion layer R.

In addition, a microlens Z31 is disposed on the green filter F31. A microlens Z32 is disposed on the magenta filter F32. At this time, the microlens Z31 can have a larger collecting area than the collecting area of the microlens Z32. For example, the microlens Z31 is set to have a larger size than the size of the green filter F31, and the microlens Z32 can be set to have a smaller size than the size of the magenta filter F32. In other words, the microlens Z31 can be protruded over the magenta filter F32 corresponding to the reduction in the size of the microlens Z32. Moreover, the size of the microlens Z31 can be set to be equal to the sizes of the green photoelectric conversion layers Gr and Gb. By individually disposing the microlenses Z32 on the magenta filters F32, it is possible to set the sizes of the microlenses Z32 to be equal to each other.

By setting the impurity diffusion layer HR31 to take a rectangular shape in place of a square shape corresponding to the reduction in the size of the microlens Z32, moreover, it is possible to decrease a width. By decreasing the width of the impurity diffusion layer HR31, it is possible to enhance a degree of freedom of a layout design of the floating diffusions FD31 to FD33 and the gate electrodes Gb3, Gg3 and Gr3.

A light collected by the microlens Z31 is incident on the green filter F31 so that a green light is extracted and is then incident on the green photoelectric conversion layers Gr and Gb. For example, the green light is photoelectrically converted in the green photoelectric conversion layer Gr so that an electric charge eg is generated.

On the other hand, a light collected by the microlens Z32 is incident on the magenta filter F32 so that a blue light and a red light are extracted and are then incident on the blue photoelectric conversion layer B and the red photoelectric conversion layer R. The blue light is photoelectrically converted in the blue photoelectric conversion layer B so that an electric charge eb is generated and is then stored in the blue photoelectric conversion layer B. Moreover, the red light is photoelectrically converted in the red photoelectric conversion layer R so that an electric charge er is generated and is then stored in the red photoelectric conversion layer R.

By setting a collecting area of the microlens Z31 to be larger than that of the microlens Z32, it is possible to enhance a sensitivity of a green pixel g. By setting the sizes of the microlenses Z31 to be equal to each other for the green photoelectric conversion layers Gr and Gb, it is possible to reduce a difference in a sensitivity between the green photoelectric conversion layers Gr and Gb.

### Fifth Embodiment

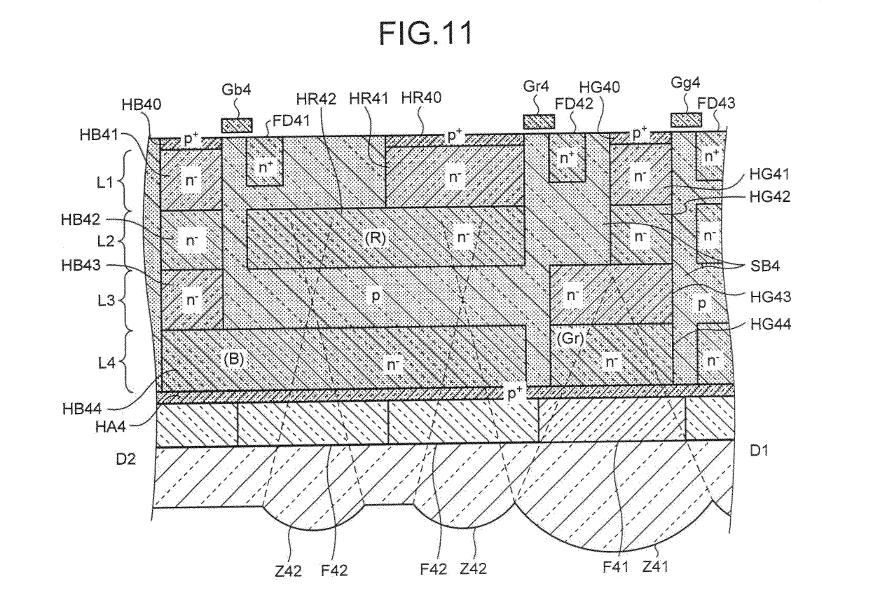

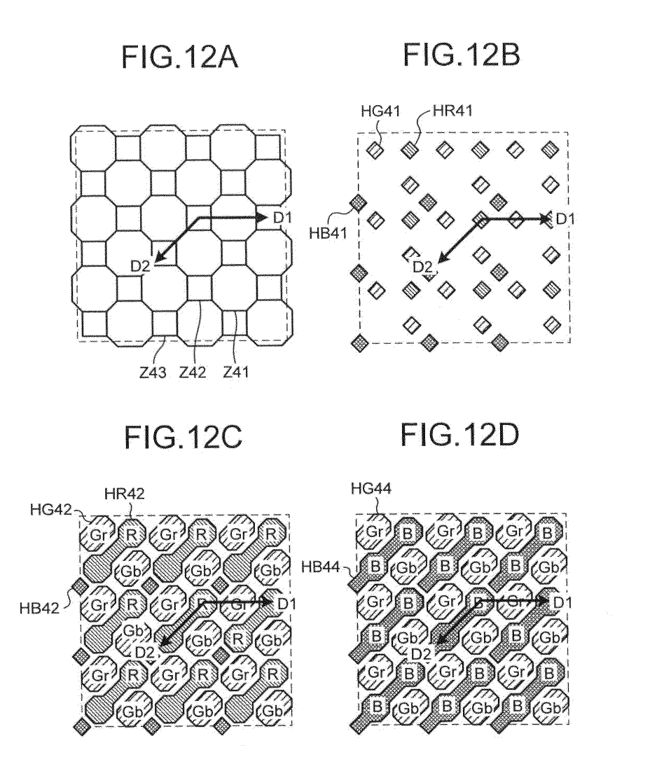

FIG. 11 is a cross-sectional view showing an example of a structure of a pixel cell in a solid-state imaging device according to a fifth embodiment. FIG. 12A is a plan view showing an example of a structure of a microlens in FIG. 11, FIG. 12B is a plan view showing an example of a structure of a first concentration distribution layer in FIG. 11, FIG. 12C is a plan view showing an example of a structure of a second concentration distribution layer in FIG. 11, and FIG. 12D is a plan view showing an example of a structure of a fourth concentration distribution layer in FIG. 11. In the fifth embodiment, a backside-illumination type CMOS image sensor is taken as an example.

In FIG. 11 and FIGS. 12A to 12D, a first concentration distribution layer L1, a second concentration distribution layer L2, a third concentration distribution layer L3 and a fourth concentration distribution layer L4 are sequentially formed on a semiconductor layer SB4 from a surface side toward a back side. A red photoelectric conversion layer R, green photoelectric conversion layers Gr and Gb, and a blue photoelectric conversion layer B are formed on the semiconductor layer SB4.

The green photoelectric conversion layers Gr and Gb are disposed so as not to overlap with the red photoelectric conversion layer R and the blue photoelectric conversion layer B in a depth direction. The blue photoelectric conversion layer B is disposed in such a manner that at least a part overlaps with the red photoelectric conversion layer R in the depth direction. Moreover, the blue photoelectric conversion layer B, the green photoelectric conversion layers Gr and Gb and the red photoelectric conversion layer R are constituted to have larger areas on the back side than areas on the surface side of the semiconductor layer SB4.

More specifically, the blue photoelectric conversion layer B is provided with impurity diffusion layers HB41 to HB44. The impurity diffusion layers HB41 to HB44 are disposed on the first concentration distribution layer L1, the second concentration distribution layer L2, the third concentration distribution layer L3 and the fourth concentration distribution layer L4, respectively. The impurity diffusion layer HB44 has a larger area than the area of the impurity diffusion layer HB41. The impurity diffusion layers HB42 and HB43 can have areas set to be equal to the area of the impurity diffusion layer HB41. Moreover, the impurity diffusion layer HB44 can be disposed integrally over two adjacent pixels in a diagonal direction.

Impurity diffusion layers HG41 to HG44 are provided on the green photoelectric conversion layer Gr. The impurity diffusion layers HG41 to HG44 are disposed on the first concentration distribution layer L1, the second concentration distribution layer L2, the third concentration distribution layer L3 and the fourth concentration distribution layer L4, respectively. The impurity diffusion layer HG44 has a larger area than the area of the impurity diffusion layer HG41. The impurity diffusion layer HG43 can have an area set to be equal to that of the impurity diffusion layer HG44. The impurity diffusion layer HG42 can have an area set to be equal to that of the impurity diffusion layer HG41.

Impurity diffusion layers HR41 and HR42 are provided on the red photoelectric conversion layer R. The impurity diffusion layers HR41 and HR42 are disposed on the first concentration distribution layer L1 and the second concentration distribution layer L2, respectively. Moreover, the impurity diffusion layer HR42 is disposed in such a manner that at least a part overlaps with the impurity diffusion layer HB44 in the depth direction. Furthermore, the impurity diffusion layer HR42 can be disposed integrally over two adjacent pixels in the diagonal direction.

In order to reduce the area of the impurity diffusion layer HB41 in the first concentration distribution layer L1 while ensuring a symmetry of a layout between the green photoelectric conversion layers Gr and Gb, it is preferable that the impurity diffusion layer HB41 should be disposed between the impurity diffusion layers HG41 of the green photoelectric conversion layers Gr and Gb as shown in FIG. 12B, and the impurity diffusion layer HB41 can be disposed with an inclination to the impurity diffusion layer HR41.

In addition, pinning layers HB40, HR40 and HG40 are laminated on the impurity diffusion layers HB41, HR41 and HG41, respectively. A pinning layer HA4 is formed on a back face of the semiconductor layer SB4.

Moreover, floating diffusions FD41, FD42 and FD43 are formed in a clearance among the red photoelectric conversion layer R, the green photoelectric conversion layers Gr and Gb, and the blue photoelectric conversion layer B at the surface side of the semiconductor layer SB4.

Furthermore, a gate electrode Gb4 is disposed between the blue photoelectric conversion layer B and the floating diffusion FD41, a gate electrode Gr4 is disposed between the red photoelectric conversion layer R and the floating diffusion FD42, and a gate electrode Gg4 is disposed between the green photoelectric conversion layer Gr and the floating diffusion FD43 over the semiconductor layer SB4.

A green filter F41 and a magenta filter F42 are formed on the back side of the semiconductor layer SB4. The green filter F41 is disposed corresponding to the green photoelectric conversion layers Gr and Gb. The magenta filter F42 is disposed corresponding to the blue photoelectric conversion layer B and the red photoelectric conversion layer R. The green filter F41 and the magenta filter F42 can be constituted in the same manner as the green filter F31 and the magenta filter F32 in FIG. 10B.

Furthermore, a microlens Z41 is disposed on the green filter F41. A microlens Z42 is disposed on the magenta filter F42. At this time, the microlens Z41 can have a larger collecting area than the collecting area of the microlens Z42. By causing the red photoelectric conversion layer R to have a two-layer structure including the impurity diffusion layers HR41 and HR42, moreover, it is possible to reduce a width of the impurity diffusion layer HR41. The microlenses Z41 and Z42 can be constituted in the same manner as the microlenses Z31 and Z32 in FIG. 10A.

A light collected by the microlens Z41 is incident on the green filter F41 so that a green light is extracted and is then incident on the green photoelectric conversion layers Gr and Gb. For example, the green light is photoelectrically converted in the green photoelectric conversion layer Gr so that an electric charge eg is generated.

On the other hand, a light collected by the microlens Z42 is incident on the magenta filter F42 so that a blue light and a red light are extracted and are then incident on the blue photoelectric conversion layer B and the red photoelectric conversion layer R. The blue light is photoelectrically converted in the blue photoelectric conversion layer B so that an electric charge eb is generated and is then stored in the blue photoelectric conversion layer B. Moreover, the red light is photoelectrically converted in the red photoelectric conversion layer R so that an electric charge er is generated and is then stored in the red photoelectric conversion layer R.

By setting a collecting area of the microlens Z41 to be larger than that of the microlens Z42, it is possible to enhance a sensitivity of a green pixel g. By setting the concentration distribution layer to have a four-layer structure and disposing the impurity diffusion layer HR42 on the second concentration distribution layer L2, moreover, it is possible to reduce the size of the impurity diffusion layer HR41 in the first concentration distribution layer L1 without deteriorating the sensitivity of the red photoelectric conversion layer R. Consequently, it is possible to enhance a degree of freedom of a layout design of the row selecting transistors TD1 and TD2, the amplifying transistors TA1 and TA2, the reset transistors TS1 and TS2, and the reading transistors TB, TR, TGr and TGb in FIG. 2. For example, it is possible to reduce a 1/f (RTS) noise by increasing the sizes of the amplifying transistors TA1 and TA2. By decreasing the areas of the floating diffusions FD41, FD42 and FD43, moreover, it is possible to increase a conversion gain, thereby reducing a noise generated in a circuit in a subsequent stage. Consequently, it is possible to enhance the sensitivity.

### Sixth Embodiment

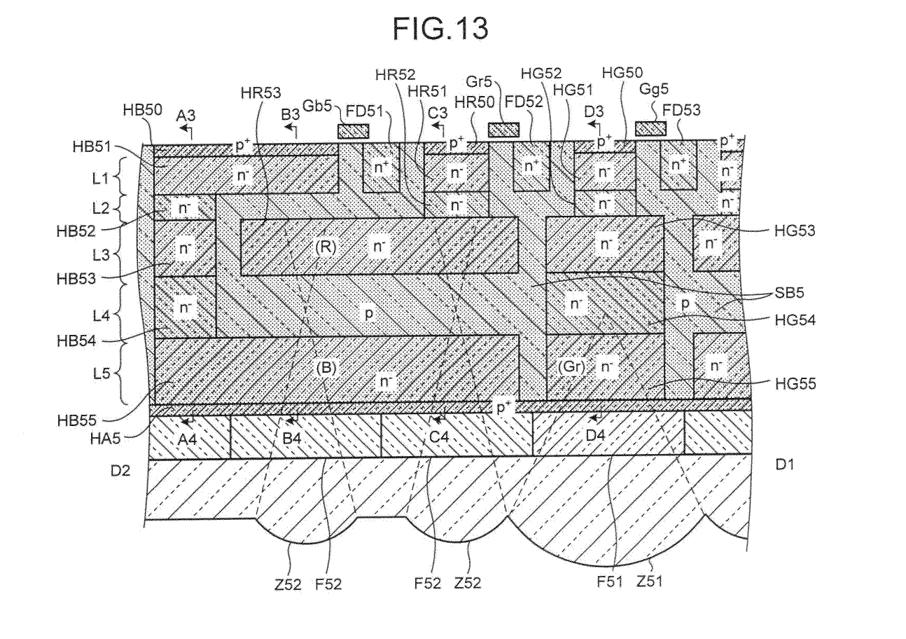

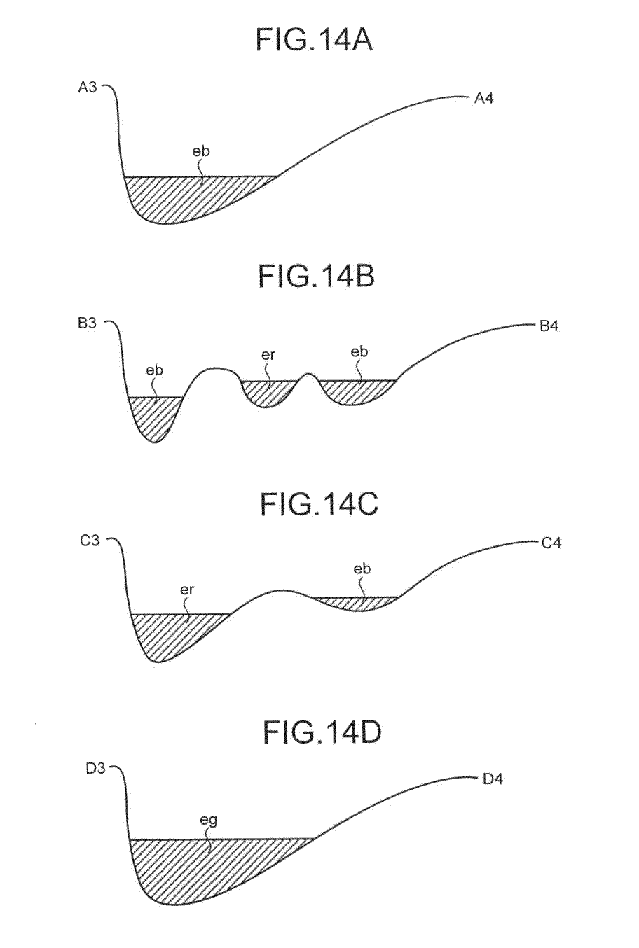

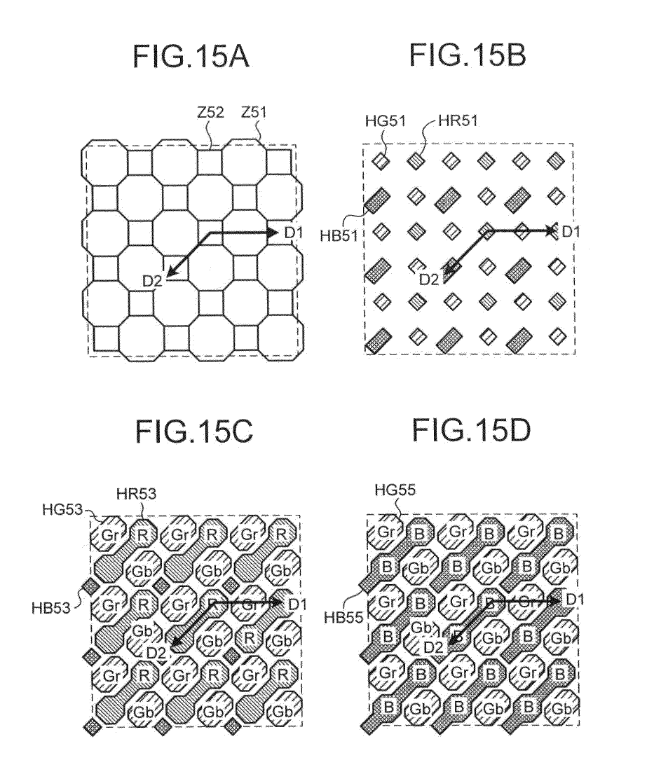

FIG. 13 is a cross-sectional view showing an example of a structure of a pixel cell in a solid-state imaging device according to a sixth embodiment. FIG. 14A is a view showing a potential distribution along an A3-A4 line in FIG. 13, FIG. 14B is a view showing a potential distribution along a B3-B4 line in FIG. 13, FIG. 14C is a view showing a potential distribution along a C3-C4 line in FIG. 13, and FIG. 14D is a view showing a potential distribution along a D3-D4 line in FIG. 13. FIG. 15A is a plan view showing an example of a structure of a microlens in FIG. 13, FIG. 15B is a plan view showing an example of a structure of a first concentration distribution layer in FIG. 13, FIG. 15C is a plan view showing an example of a structure of a third concentration distribution layer in FIG. 13, and FIG. 15D is a plan view showing an example of a structure of a fifth concentration distribution layer in FIG. 13. In the sixth embodiment, a backside-illumination type CMOS image sensor is taken as an example.

In FIG. 13 and FIGS. 15A to 15D, a first concentration distribution layer L1, a second concentration distribution layer L2, a third concentration distribution layer L3, a fourth concentration distribution layer L4, and a fifth concentration distribution layer L5 are sequentially formed on a semiconductor layer SB5 from a surface side toward a back side. A red photoelectric conversion layer R, green photoelectric conversion layers Gr and Gb, and a blue photoelectric conversion layer B are formed on the semiconductor layer SB5.

The green photoelectric conversion layers Gr and Gb are disposed so as not to overlap with the red photoelectric conversion layer R and the blue photoelectric conversion layer B in a depth direction. The blue photoelectric conversion layer B is disposed in such a manner that at least a part overlaps with the red photoelectric conversion layer R in the depth direction. Moreover, the blue photoelectric conversion layer B, the green photoelectric conversion layers Gr and Gb and the red photoelectric conversion layer R are constituted to have larger areas on the back side than areas on the surface side of the semiconductor layer SB5.

More specifically, the blue photoelectric conversion layer B is provided with impurity diffusion layers HB51 to HB55. The impurity diffusion layers HB51 to HB55 are disposed on the first concentration distribution layer L1, the second concentration distribution layer L2, the third concentration distribution layer L3, the fourth concentration distribution layer L4 and the fifth concentration distribution layer L5, respectively. The impurity diffusion layer HB55 has a larger area than the area of the impurity diffusion layer HB51. The impurity diffusion layers HB52, HB53 and HB54 can have areas set to be smaller than the area of the impurity diffusion layer HB51. Furthermore, the impurity diffusion layer HB55 can be disposed integrally over two adjacent pixels in a diagonal direction.

Impurity diffusion layers HG51 to HG55 are provided on the green photoelectric conversion layer Gr. The impurity diffusion layers HG51 to HG55 are disposed on the first concentration distribution layer L1, the second concentration distribution layer L2, the third concentration distribution layer L3, the fourth concentration distribution layer L4 and the fifth concentration distribution layer L5, respectively. The impurity diffusion layer HG54 has a larger area than the area of the impurity diffusion layer HG51. The impurity diffusion layers HG53 and HG55 can have areas set to be equal to the area of the impurity diffusion layer HG54. The impurity diffusion layer HG52 can have an area set to be equal to the area of the impurity diffusion layer HG51.

Impurity diffusion layers HG51 to HG53 are provided on the red photoelectric conversion layer R. The impurity diffusion layers HG51 to HG53 are disposed on the first concentration distribution layer L1, the second concentration distribution layer L2 and the third concentration distribution layer L3, respectively. Moreover, the impurity diffusion layer HR53 is disposed in such a manner that at least a part overlaps with the impurity diffusion layers HB51 and HB55 in a depth direction. Furthermore, the impurity diffusion layer HR53 can be disposed integrally over two adjacent pixels in the diagonal direction.

As shown in FIG. 15B, the impurity diffusion layer HB51 can be disposed between the impurity diffusion layers HG51 of the green photoelectric conversion layer Gb, and an inclination of the arrangement with respect to the impurity diffusion layer HR51 can be reduced as compared with the layout method for the impurity diffusion layer HB41 in FIG. 12B.

Moreover, pining layers HB50, HR50 and HG50 are provided on the impurity diffusion layers HB51, HR51 and HG51, respectively. A pinning layer HA5 is formed on the back face of the semiconductor layer SB5.

As shown in FIG. 14A, a laminated portion of the impurity diffusion layers HB51 to HB55 can have a downward gradient of a potential from the impurity diffusion layer HB55 toward the impurity diffusion layer HB51 in such a manner that an electric charge eb generated in the impurity diffusion layer HB55 can be moved to the impurity diffusion layer HB51. As shown in FIG. 14B, moreover, a laminated portion of the impurity diffusion layers HB51, HR53 and HB55 can have a peak of the potential between the impurity diffusion layers HR53 and HB55 and between the impurity diffusion layers HR53 and HB51 in order to prevent an electric charge er generated in the impurity diffusion layer HR53 from being mixed into the electric charge eb generated in the impurity diffusion layer HB55. As shown in FIG. 14C, furthermore, a laminated portion of the impurity diffusion layers HR51 to HR53 and HB55 can have a peak of the potential between the impurity diffusion layers HR53 and HB55 in order to prevent an electric charge er generated in the impurity diffusion layer HR53 from being mixed into the electric charge eb generated in the impurity diffusion layer HB55. As shown in FIG. 14D, furthermore, a laminated portion of the impurity diffusion layers HG51 to HG55 can have a downward gradient of the potential from the impurity diffusion layer HR55 toward the impurity diffusion layer HG51 in such a manner that an electric charge eg generated in the impurity diffusion layers HG53 to HG55 can be moved to the impurity diffusion layer HG51.

In addition, floating diffusions FD51, FD52 and FD53 are formed in a clearance among the red photoelectric conversion layer R, the green photoelectric conversion layers Gr and Gb, and the blue photoelectric conversion layer B at the surface side of the semiconductor layer SB5.

Moreover, a gate electrode Gb5 is disposed between the blue photoelectric conversion layer B and the floating diffusion FD51, a gate electrode Gr5 is disposed between the red photoelectric conversion layer R and the floating diffusion FD52, and a gate electrode Gg5 is disposed between the green photoelectric conversion layer Gr and the floating diffusion FD53 over the semiconductor layer SB5.

A green filter F51 and a magenta filter F52 are formed on the back side of the semiconductor layer SB5. The green filter F51 is disposed corresponding to the green photoelectric conversion layers Gr and Gb. The magenta filter F52 is disposed corresponding to the blue photoelectric conversion layer B and the red photoelectric conversion layer R. The green filter F51 and the magenta filter F52 can be constituted in the same manner as the green filter F31 and the magenta filter F32 in FIG. 10B.

Furthermore, a microlens Z51 is disposed on the green filter F51. A microlens Z52 is disposed on the magenta filter F52. At this time, the microlens Z51 can have a larger collecting area than the collecting area of the microlens Z52. In addition, it is possible to reduce a width of the impurity diffusion layer HR51 corresponding to the decrease in the collecting area of the microlens Z52. The microlenses Z51 and Z52 can be constituted in the same manner as the microlenses Z31 and Z32 in FIG. 10A.

A light collected by the microlens Z51 is incident on the green filter F51 so that a green light is extracted and is then incident on the green photoelectric conversion layers Gr and Gb. For example, the green light is photoelectrically converted in the green photoelectric conversion layer Gr so that the electric charge eg is generated.

On the other hand, a light collected by the microlens Z52 is incident on the magenta filter F52 so that a blue light and a red light are extracted and are then incident on the blue photoelectric conversion layer B and the red photoelectric conversion layer R. The blue light is photoelectrically converted in the blue photoelectric conversion layer B so that the electric charge eb is generated and is then stored in the blue photoelectric conversion layer B. Moreover, the red light is photoelectrically converted in the red photoelectric conversion layer R so that the electric charge er is generated and is then stored in the red photoelectric conversion layer R.

By causing the microlens Z51 to have a larger collecting area than the collecting area of the microlens Z52, it is possible to enhance a sensitivity of the green pixel g. By causing the concentration distribution layer to have a five-layer structure and disposing the impurity diffusion layers HB51 and HB55 on and under the impurity diffusion layer HR53 respectively, moreover, it is possible to decrease the size of the impurity diffusion layer HR51 in the first concentration distribution layer L1 and to reduce an inclination of the arrangement of the impurity diffusion layer HB51 without deteriorating a sensitivity of the red photoelectric conversion layer R. Therefore, it is possible to improve a symmetry of the arrangement and to enhance a degree of freedom of a layout design while increasing a layout area of the row selecting transistors TD1 and TD2, the amplifying transistors TA1 and TA2, the reset transistors TS1 and TS2, and the reading transistors TB, TR, TGr and TGb in FIG. 2. For example, by increasing the sizes of the amplifying transistors TA1 and TA2, it is possible to reduce a 1/f (RTS) noise. By decreasing the areas of the FD51, FD52 and FD53, moreover, it is possible to increase a conversion gain, thereby reducing a noise generated in a circuit in a subsequent stage. Consequently, it is possible to enhance the sensitivity.

### Seventh Embodiment

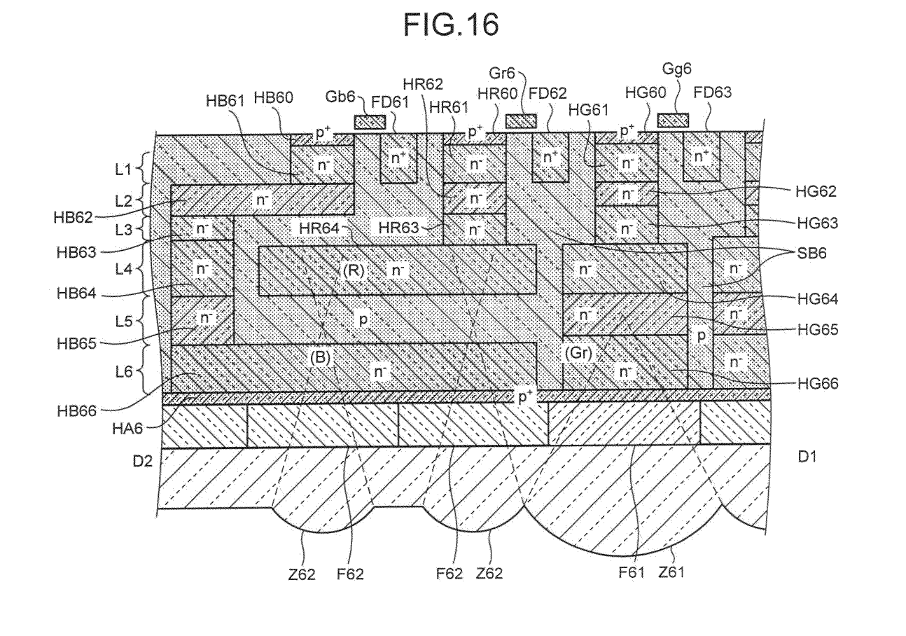

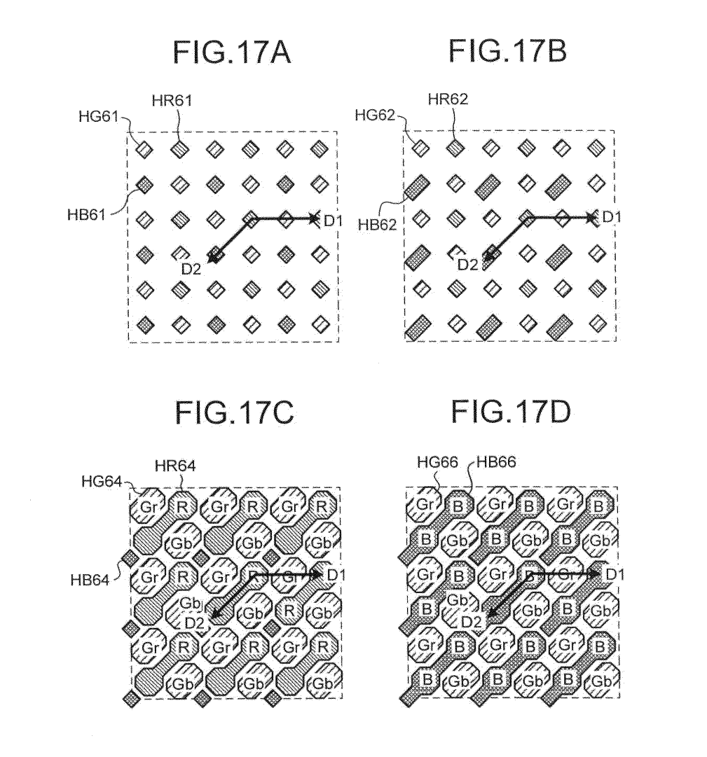

FIG. 16 is a cross-sectional view showing an example of a structure of a pixel cell in a solid-state imaging device according to a seventh embodiment. FIG. 17A is a plan view showing an example of a structure of a first concentration distribution layer in FIG. 16, FIG. 17B is a plan view showing an example of a structure of a second concentration distribution layer in FIG. 16, FIG. 17C is a plan view showing an example of a structure of a forth concentration distribution layer in FIG. 16, and FIG. 17D is a plan view showing an example of a structure of a sixth concentration distribution layer in FIG. 16. In the seventh embodiment, a backside-illumination type CMOS image sensor is taken as an example.

In FIG. 16 and FIGS. 17A to 17D, a first concentration distribution layer L1, a second concentration distribution layer L2, a third concentration distribution layer L3, a fourth concentration distribution layer L4, a fifth concentration distribution layer L5 and a sixth concentration distribution layer L6 are sequentially formed on a semiconductor layer SB6 from a surface side toward a back side. A red photoelectric conversion layer R, green photoelectric conversion layers Gr and Gb, and a blue photoelectric conversion layer B are formed on the semiconductor layer SB6.

The green photoelectric conversion layers Gr and Gb are disposed so as not to overlap with the red photoelectric conversion layer R and the blue photoelectric conversion layer B in a depth direction. The blue photoelectric conversion layer B is disposed in such a manner that at least a part overlaps with the red photoelectric conversion layer R in the depth direction. Moreover, the blue photoelectric conversion layer B, the green photoelectric conversion layers Gr and Gb and the red photoelectric conversion layer R are constituted to have larger areas on the back side than areas on the surface side of the semiconductor layer SB6.

More specifically, the blue photoelectric conversion layer B is provided with impurity diffusion layers HB61 to HB66. The impurity diffusion layers HB61 to HB66 are disposed on the first concentration distribution layer L1, the second concentration distribution layer L2, the third concentration distribution layer L3, the fourth concentration distribution layer L4, the fifth concentration distribution layer L5 and the sixth concentration distribution layer L6, respectively. The impurity diffusion layer HB66 has a larger area than the area of the impurity diffusion layer HB61. The impurity diffusion layers HB62 to HB65 can have areas set to be smaller than the area of the impurity diffusion layer HB66. Moreover, the impurity diffusion layer HB66 can be disposed integrally over two adjacent pixels in a diagonal direction.

Impurity diffusion layers HG61 to HG66 are provided on the green photoelectric conversion layer Gr. The impurity diffusion layers HG61 to HG66 are disposed on the first concentration distribution layer L1, the second concentration distribution layer L2, the third concentration distribution layer L3, the fourth concentration distribution layer L4, the fifth concentration distribution layer L5 and the sixth concentration distribution layer L6, respectively. The impurity diffusion layer HG65 has a larger area than the area of the impurity diffusion layer HG61. The impurity diffusion layers HG66 and HG64 can have areas set to be equal to the area of the impurity diffusion layer HG65. The impurity diffusion layers HG62 and HG63 can have areas set to be equal to the area of the impurity diffusion layer HG61.

Impurity diffusion layers HR61 to HR64 are provided on the red photoelectric conversion layer R. The impurity diffusion layers HR61 to HR64 are disposed on the first concentration distribution layer L1, the second concentration distribution layer L2, the third concentration distribution layer L3 and the fourth concentration distribution layer L4, respectively. Moreover, the impurity diffusion layer HR64 is disposed in such a manner that at least a part overlaps with the impurity diffusion layers HB62 and HB66 in the depth direction. Furthermore, the impurity diffusion layer HR64 can be disposed integrally over two adjacent pixels in the diagonal direction.

As shown in FIG. 17A, the impurity diffusion layer HB61 can be disposed between the impurity diffusion layers HG61 of the green photoelectric conversion layer Gb, and furthermore, the shapes and areas of the impurity diffusion layers HB61, HG61 and HR61 can be set to be equal. As compared with the layout method for the impurity diffusion layers HB51, HG51 and HR51 in FIG. 15B, therefore, it is possible to enhance a uniformity of the layout of the impurity diffusion layers HB61, HG61 and HR61.

In addition, pinning layers HB60, HR60 and HG60 are provided on the impurity diffusion layers HB61, HR61 and HG61, respectively. A pinning layer HA6 is formed on the back face of the semiconductor layer SB6.

Moreover, floating diffusions FD61, FD62 and FD63 are formed in a clearance among the red photoelectric conversion layer R, the green photoelectric conversion layers Gr and Gb, and the blue photoelectric conversion layer B at the surface side of the semiconductor layer SB6.

Furthermore, a gate electrode Gb6 is disposed between the blue photoelectric conversion layer B and the floating diffusion FD61, a gate electrode Gr6 is disposed between the red photoelectric conversion layer R and the floating diffusion FD62, and a gate electrode Gg6 is disposed between the green photoelectric conversion layer Gr and the floating diffusion FD63 over the semiconductor layer SB6.

A green filter F61 and a magenta filter F62 are formed on the back side of the semiconductor layer SB6. The green filter F61 is disposed corresponding to the green photoelectric conversion layers Gr and Gb. The magenta filter F62 is disposed corresponding to the blue photoelectric conversion layer B and the red photoelectric conversion layer R. The green filter F61 and the magenta filter F62 can be constituted in the same manner as the green filter F31 and the magenta filter F32 in FIG. 10B.

Furthermore, a microlens Z61 is disposed on the green filter F61. A microlens Z62 is disposed on the magenta filter F62. At this time, the microlens Z61 can have a larger collecting area than the collecting area of the microlens Z62. In addition, it is possible to reduce a width of the impurity diffusion layer HR61 corresponding to the decrease in the collecting area of the microlens Z62. The microlenses Z61 and Z62 can be constituted in the same manner as the microlenses Z31 and Z32 in FIG. 10A.

A light collected by the microlens Z61 is incident on the green filter F61 so that a green light is extracted and is then incident on the green photoelectric conversion layers Gr and Gb. For example, the green light is photoelectrically converted in the green photoelectric conversion layer Gr so that an electric charge eg is generated.

On the other hand, a light collected by the microlens Z62 is incident on the magenta filter F62 so that a blue light and a red light are extracted and are then incident on the blue photoelectric conversion layer B and the red photoelectric conversion layer R. The blue light is photoelectrically converted in the blue photoelectric conversion layer B so that an electric charge eb is generated and is then stored in the blue photoelectric conversion layer B. Moreover, the red light is photoelectrically converted in the red photoelectric conversion layer R so that an electric charge er is generated and is then stored in the red photoelectric conversion layer R.

By causing the microlens Z61 to have a larger collecting area than the collecting area of the microlens Z62, it is possible to enhance a sensitivity of the green pixel g. By causing the concentration distribution layer to have a six-layer structure and disposing the impurity diffusion layers HB62 and HB66 on and under the impurity diffusion layer HR64 respectively, it is possible to decrease the sizes of the impurity diffusion layers HR61 and HB61 in the first concentration distribution layer L1 and to eliminate an inclination of the arrangement of the impurity diffusion layer HB61 without reducing a sensitivity of the red photoelectric conversion layer R. Therefore, it is possible to ensure a symmetry of the arrangement and to enhance a degree of freedom of a layout design while increasing a layout area of the row selecting transistors TD1 and TD2, the amplifying transistors TA1 and TA2, the reset transistors TS1 and TS2, and the reading transistors TB, TR, TGr and TGb in FIG. 2. For example, by increasing the sizes of the amplifying transistors TA1 and TA2, it is possible to reduce a 1/f (RTS) noise. By decreasing the areas of the floating diffusions FD61, FD62 and FD63, moreover, it is possible to increase a conversion gain, thereby reducing a noise generated in a circuit in a subsequent stage. Consequently, it is possible to enhance the sensitivity.

Although the description has been given to the method using the microlens in FIG. 10A and the filter structure in FIG. 10B in the fourth to seventh embodiments, it is also possible to use the microlenses Z1 and Z2 in FIG. 5A, the microlenses Z11 and Z12 in FIG. 6A, the filter structure in FIG. 6B or the filter structure in FIG. 8B.

### Eighth Embodiment

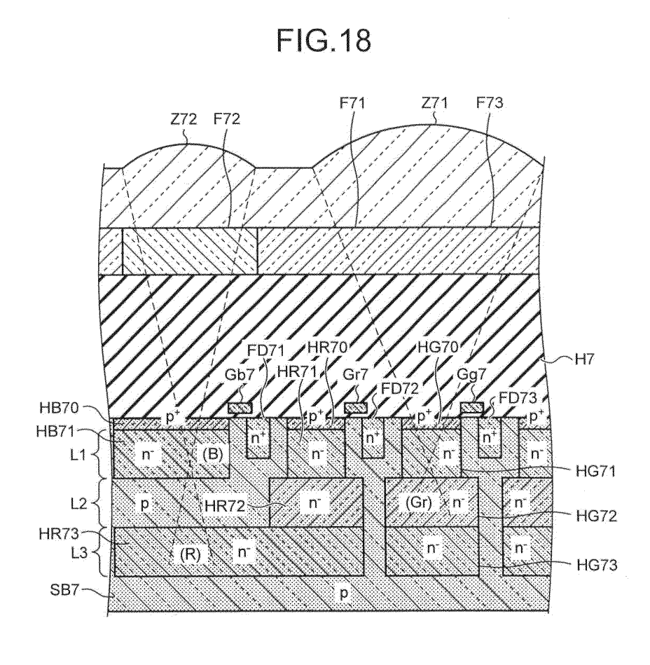

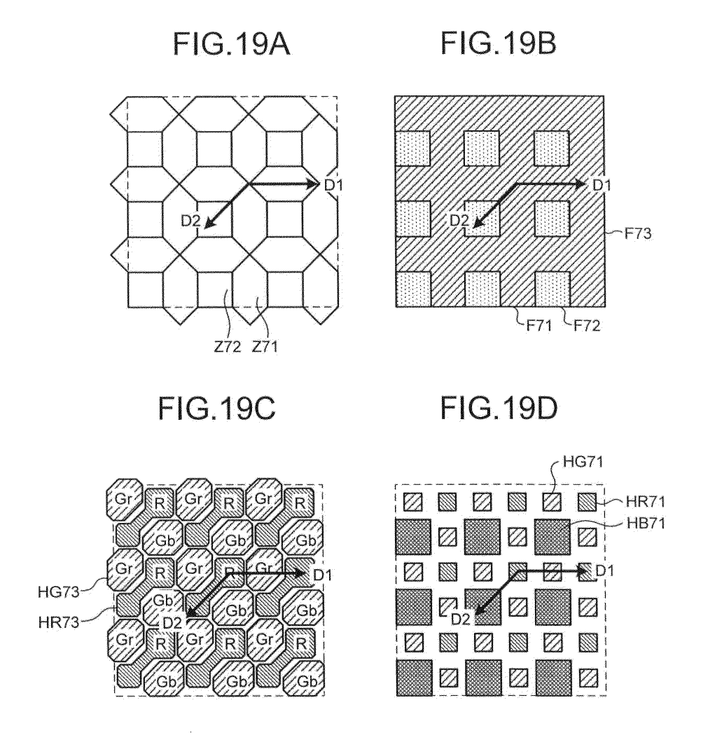

FIG. 18 is a cross-sectional view showing an example of a structure of a pixel cell in a solid-state imaging device according to an eighth embodiment. FIG. 19A is a plan view showing an example of a structure of a microlens in FIG. 18, FIG. 19B is a plan view showing an example of a structure of a color filter in FIG. 18, FIG. 19C is a plan view showing an example of a structure of a third concentration distribution layer in FIG. 18, and FIG. 19D is a plan view showing an example of a structure of a first concentration distribution layer in FIG. 18. In the eighth embodiment, a surface-illumination type CMOS image sensor is taken as an example.

In FIG. 18 and FIGS. 19A to 19D, a first concentration distribution layer L1, a second concentration distribution layer L2 and a third concentration distribution layer L3 are sequentially formed on a semiconductor layer SB7 from a surface side toward a back side. A red photoelectric conversion layer R, green photoelectric conversion layers Gr and Gb, and a blue photoelectric conversion layer B are formed on the semiconductor layer SB7.

The green photoelectric conversion layers Gr and Gb are disposed so as not to overlap with the red photoelectric conversion layer R and the blue photoelectric conversion layer B in a depth direction. The blue photoelectric conversion layer B is disposed in such a manner that at least a part overlaps with the red photoelectric conversion layer R in the depth direction. Moreover, the blue photoelectric conversion layer B and the green photoelectric conversion layers Gr and Gb are constituted to have larger areas on the back side than the areas on the surface side of the semiconductor layer SB7.

More specifically, the blue photoelectric conversion layer B is provided with an impurity diffusion layer HB71. The impurity diffusion layer HB71 is disposed on the first concentration distribution layer L1.

Impurity diffusion layers HG71 to HG73 are provided on the green photoelectric conversion layer Gr. The impurity diffusion layers HG71 to HG73 are disposed on the first concentration distribution layer L1, the second concentration distribution layer L2 and the third concentration distribution layer L3, respectively. The impurity diffusion layer HG73 has a larger area than the area of the impurity diffusion layer HG71. The impurity diffusion layer HG72 can have an area set to be equal to the area of the impurity diffusion layer HG73.

Impurity diffusion layers HR71 to HR73 are provided on the red photoelectric conversion layer R. The impurity diffusion layers HR71 to HR73 are disposed on the first concentration distribution layer L1, the second concentration distribution layer L2 and the third concentration distribution layer L3, respectively. Moreover, the impurity diffusion layer HR73 is disposed in such a manner that at least a part overlaps with the impurity diffusion layer HB71 in the depth direction. The impurity diffusion layer HR73 has a larger area than the area of the impurity diffusion layer HR71. The impurity diffusion layer HR72 can have an area set to be smaller than the area of the impurity diffusion layer HR73.

In addition, pinning layers HB70, HR70 and HG70 are provided on the impurity diffusion layers HB71, HR71 and HG71, respectively. Moreover, floating diffusions FD71, FD72 and FD73 are formed in a clearance among the red photoelectric conversion layer R, the green photoelectric conversion layers Gr and Gb, and the blue photoelectric conversion layer B at the surface side of the semiconductor layer SB7.

Furthermore, a gate electrode Gb7 is disposed between the blue photoelectric conversion layer B and the floating diffusion FD71, a gate electrode Gr7 is disposed between the red photoelectric conversion layer R and the floating diffusion FD72, and a gate electrode Gg7 is disposed between the green photoelectric conversion layer Gr and the floating diffusion FD73 over the semiconductor layer SB7. In addition, a wiring layer H7 is formed on the gate electrodes Gb7, Gg7 and Gr7. It is possible to form, on the wiring layer H7, a wiring to be used for the row selecting transistors TD1 and TD2, the amplifying transistors TA1 and TA2, the reset transistors TS1 and TS2, and the reading transistors TB, TR, TGr and TGb in FIG. 2.

Green filters F71 and F73 and a magenta filter F72 are formed on the wiring layer H7. The green filters F71 and F73 are disposed corresponding to the green photoelectric conversion layers Gr and Gb. The magenta filter F72 is disposed corresponding to the blue photoelectric conversion layer B and the red photoelectric conversion layer R.

Furthermore, a microlens Z71 is disposed on the green filters F71 and F73. A microlens Z72 is disposed on the magenta filter F72. At this time, the microlens Z71 can have a larger collecting area than the collecting area of the microlens Z72.

A light collected by the microlens Z71 is incident on the green filters F71 and F73 so that a green light is extracted and is then incident on the green photoelectric conversion layers Gr and Gb. For example, the green light is photoelectrically converted in the green photoelectric conversion layer Gr so that an electric charge eg is generated.

On the other hand, a light collected by the microlens Z72 is incident on the magenta filter F72 so that a blue light and a red light are extracted and are then incident on the blue photoelectric conversion layer B and the red photoelectric conversion layer R. The blue light is photoelectrically converted in the blue photoelectric conversion layer B so that an electric charge eb is generated and is then stored in the blue photoelectric conversion layer B. Moreover, the red light is photoelectrically converted in the red photoelectric conversion layer R so that an electric charge er is generated and is then stored in the red photoelectric conversion layer R.

By causing the microlens Z71 to have a larger collecting area than the collecting area of the microlens Z72, it is possible to enhance a sensitivity of a green pixel g, thereby enhancing an S/N ratio of a luminance signal Y. Moreover, the blue photoelectric conversion layer B and the red photoelectric conversion layer R are caused to overlap with each other in the depth direction, and furthermore, the green photoelectric conversion layers Gr and Gb are prevented from overlapping with the blue photoelectric conversion layer B and the red photoelectric conversion layer R. Consequently, it is possible to suppress a deterioration in a color isolation of the blue, green and red lights while increasing light receiving areas of the blue photographic conversion layer B and the red photoelectric conversion layer R. Therefore, it is possible to suppress a deterioration in a color reproducibility while enhancing a sensitivity and a saturation charge quantity of each of the blue pixel b and the red pixel r.

### Ninth Embodiment

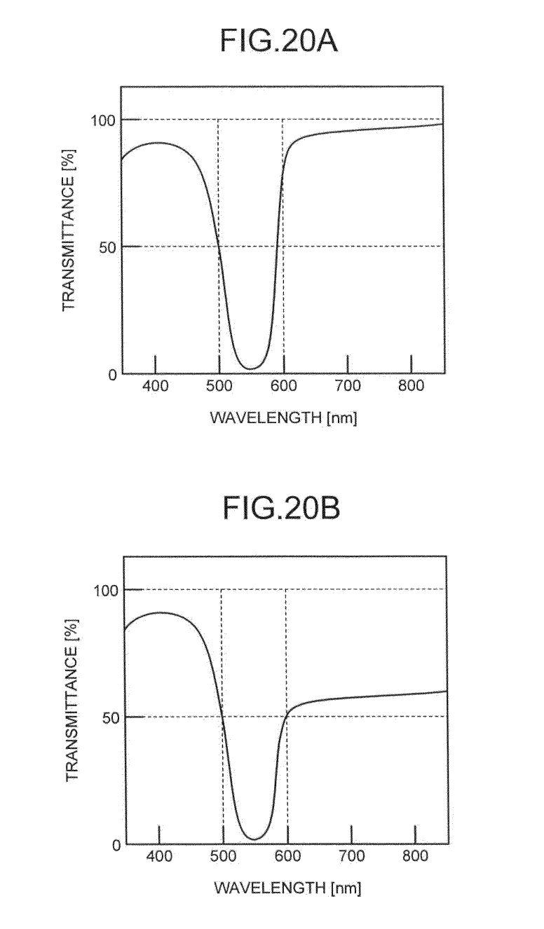

FIGS. 20A and 20B are charts showing a spectral characteristic of a magenta filter to be applied to a solid-state imaging device according to a ninth embodiment.

In FIG. 20A, in the magenta filter, a spectral characteristic is set in such a manner that a blue light and a red light are transmitted almost equally.

On the other hand, in FIG. 20B, a peak of the transmittance of the red light is reduced with respect to the blue light in the magenta filter. It is preferable that the transmittance of the red light should have a peak reduced to be 40% to 80% with respect to the transmittance of the blue color.

In the case in which the filter structure of FIG. 10B is used, it is also possible to cause the magenta filter F32 in the same row as the green photoelectric conversion layer Gr to have the spectral characteristic in FIG. 20A, and to cause the magenta filter F32 in the same row as the green photoelectric conversion layer Gb to have the spectral characteristic of FIG. 20B. Consequently, it is possible to enhance a purity of the blue light which is incident on the blue photoelectric conversion layer B without using the blue filter F4 in FIG. 8B. Thus, it is possible to enhance a color reproducibility of the blue color while improving an S/N ratio of a blue signal.

Although the sizes of all the color filters are set to be equal to each other for a single pixel in the embodiments according to the present invention, it is possible to change the sizes of the color filters corresponding to the size of the microlens. Although the microlens for green is enlarged to enhance the S/N ratio of the luminance signal, it is possible to improve both the luminance and the S/N ratio of the color to be approximately 1.3 fold by setting the sizes of the microlenses for green and magenta to be equal to each other. By setting the size of the microlens for magenta to be larger than that of the microlens for green, furthermore, it is possible to enhance the S/N ratios of the red and blue colors. In addition, it is possible to apply the present invention to a honeycomb array obtained by rotating a pixel array by 45 degrees.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a first photoelectric conversion layer provided for a first wavelength range;
a second photoelectric conversion layer provided for a second wavelength range so as not to overlap with the first photoelectric conversion layer in a depth direction;
a third photoelectric conversion layer provided for a third wavelength range in such a manner that at least a part overlaps with the first photoelectric conversion layer in the depth direction;
a first color filter provided for the first photoelectric conversion layer and the third photoelectric conversion layer and configured to transmit lights in the first wavelength range and the third wavelength range;
a second color filter provided for the second photoelectric conversion layer and configured to transmit a light of the second wavelength range;
a first collecting element configured to collect lights which are incident on the first photoelectric conversion layer and the third photoelectric conversion layer; and
a second collecting element having a larger collecting area than a collecting area of the first collecting element and configured to collect a light which is incident on the second photoelectric conversion layer.

2. The solid-state imaging device according to claim 1, wherein a peak of a transmittance of the first color filter is reduced in the third wavelength range by 40% to 80% with respect to the first wavelength range.

3. The solid-state imaging device according to claim 1, wherein an output signal forms a Bayer array by one first photoelectric conversion layer, two second photoelectric conversion layers and one third photoelectric conversion layer.

4. The solid-state imaging device according to claim 3, wherein the first wavelength range corresponds to a red light, the second wavelength range corresponds to a green light, the third wavelength range corresponds to a blue light, the first photoelectric conversion layer is a red photoelectric conversion layer, the second photoelectric conversion layer is a green photoelectric conversion layer, the third photoelectric conversion layer is a blue photoelectric conversion layer, the first color filter is a magenta filter, the second color filter is a green filter, the first collecting element is a first microlens, and the second collecting element is a second microlens.

5. The solid-state imaging device according to claim 4, wherein the green photoelectric conversion layer is disposed on a green pixel in the Bayer array, and the red photoelectric conversion layer and the blue photoelectric conversion layer are disposed on both a red pixel and a blue pixel in the Bayer array in such a manner that positions in the depth direction are different from each other.

6. The solid-state imaging device according to claim 5, wherein the green filter is disposed on two green pixels in the Bayer array, the magenta filter is disposed on the red pixel and the blue pixel in the Bayer array, the first microlens is disposed corresponding to a single pixel on the magenta filter, and the second microlens is disposed corresponding to two pixels on the green filter and a single pixel on the magenta filter.

7. The solid-state imaging device according to claim 5, wherein the green filter is disposed on two green pixels and a single blue pixel in the Bayer array, the magenta filter is disposed on one red pixel in the Bayer array, the first microlens is disposed on the magenta filter, and the second microlens is disposed on the green filter.

8. The solid-state imaging device according to claim 5, wherein the green filter is disposed on two green pixels in the Bayer array, the magenta filter is disposed on the red pixel and the blue pixel in the Bayer array, the first microlens is disposed in a partial region on the magenta filter, and the second microlens is disposed to be uniformly protruded onto the magenta filter which is adjacent to the green filter over the green filter.

9. The solid-state imaging device according to claim 5, wherein the green filter is disposed on two green pixels in the Bayer array, the magenta filter is disposed on the red pixel in the Bayer array, the blue filter is disposed on the blue pixel in the Bayer array, the first microlens is disposed in a partial region on the magenta filter, a third microlens is disposed in a partial region on the blue filter, and the second microlens is disposed to be protruded onto the magenta filter and the blue filter which are adjacent to the green filter over the green filter.

10. The solid-state imaging device according to claim 1, wherein first to third concentration distribution layers are provided on a semiconductor layer from a surface side toward a back side,
the first photoelectric conversion layer is provided on the first concentration distribution layer, and
the second and third photoelectric conversion layers are provided on the first to third concentration distribution layers.

11. The solid-state imaging device according to claim 1, wherein first to fourth concentration distribution layers are provided on a semiconductor layer from a surface side toward a back side,
the first photoelectric conversion layer is provided on the first and second concentration distribution layers, and
the second and third photoelectric conversion layers are provided on the first to fourth concentration distribution layers.

12. The solid-state imaging device according to claim 1, wherein first to fifth concentration distribution layers are provided on a semiconductor layer from a surface side toward a back side,
the first photoelectric conversion layer is provided on the first to third concentration distribution layers, and
the second and third photoelectric conversion layers are provided on the first to fifth concentration distribution layers.

13. The solid-state imaging device according to claim 1, wherein first to sixth concentration distribution layers are provided on a semiconductor layer from a surface side toward a back side,
the first photoelectric conversion layer is provided on the first to fourth concentration distribution layers, and
the second and third photoelectric conversion layers are provided on the first to sixth concentration distribution layers.

14. A solid-state imaging device comprising:
a first photoelectric conversion layer provided for a first wavelength range;
a second photoelectric conversion layer provided for a second wavelength range so as not to overlap with the first photoelectric conversion layer in a depth direction; and
a third photoelectric conversion layer provided for a third wavelength range in such a manner that at least a part overlaps with the first photoelectric conversion layer in both of upper and lower parts in the depth direction.

15. The solid-state imaging device according to claim 14, further comprising:
a first color filter provided for the first photoelectric conversion layer and the third photoelectric conversion layer and configured to transmit lights in the first wavelength range and the third wavelength range;
a second color filter provided for the second photoelectric conversion layer and configured to transmit a light of the second wavelength range;
a first collecting element configured to collect lights which are incident on the first photoelectric conversion layer and the third photoelectric conversion layer; and
a second collecting element configured to collect a light which is incident on the second photoelectric conversion layer.

16. The solid-state imaging device according to claim 15, wherein an output signal forms a Bayer array by one first photoelectric conversion layer, two second photoelectric conversion layers and one third photoelectric conversion layer.

17. The solid-state imaging device according to claim 16, wherein the first wavelength range corresponds to a red light, the second wavelength range corresponds to a green light, the third wavelength range corresponds to a blue light, the first photoelectric conversion layer is a red photoelectric conversion layer, the second photoelectric conversion layer is a green photoelectric conversion layer, the third photoelectric conversion layer is a blue photoelectric conversion layer, the first color filter is a magenta filter, the second color filter is a green filter, the first collecting element is a first microlens, and the second collecting element is a second microlens.

18. A solid-state imaging device comprising:
a first photoelectric conversion layer provided for a first wavelength range in such a manner that an area on a back side is larger than that on a surface side of a semiconductor layer;
a second photoelectric conversion layer provided for a second wavelength range so as not to overlap with the first photoelectric conversion layer in a depth direction;
a third photoelectric conversion layer provided for a third wavelength range in such a manner that at least a part overlaps with the first photoelectric conversion layer in the depth direction;
a first gate electrode formed on the surface side of the semiconductor layer and configured to read an electric charge stored in the first photoelectric conversion layer;
a second gate electrode formed on the surface side of the semiconductor layer and configured to read an electric charge stored in the second photoelectric conversion layer; and
a third gate electrode formed on the surface side of the semiconductor layer and configured to read an electric charge stored in the third photoelectric conversion layer.

19. The solid-state imaging device according to claim 18, further comprising:
a first color filter provided on the back side of the semiconductor layer corresponding to the first photoelectric conversion layer and the third photoelectric conversion layer and configured to transmit lights in the first wavelength range and the third wavelength range;
a second color filter provided on the back side of the semiconductor layer corresponding to the second photoelectric conversion layer and configured to transmit a light in the second wavelength range;
a first collecting element provided on the back side of the semiconductor layer and configured to collect lights which are incident on the first photoelectric conversion layer and the third photoelectric conversion layer; and
a second collecting element provided on the back side of the semiconductor layer and configured to collect a light which is incident on the second photoelectric conversion layer.

20. The solid-state imaging device according to claim 19, wherein the first wavelength range corresponds to a red light, the second wavelength range corresponds to a green light, the third wavelength range corresponds to a blue light, the first photoelectric conversion layer is a red photoelectric conversion layer, the second photoelectric conversion layer is a green photoelectric conversion layer, the third photoelectric conversion layer is a blue photoelectric conversion layer, the first color filter is a magenta filter, the second color filter is a green filter, the first collecting element is a first microlens, and the second collecting element is a second microlens.
